(19) United States
(12) Patent Application Publication
(10) Pub. No.: US 2013/0037312 A1
(43) Pub. Date: Feb. 14, 2013

(54) HIGH DENSITY TRACE FORMATION METHOD BY LASER ABLATION

(71) Applicants: Norihito Masuda, Yokohama (JP); Hiroaki Sato, Yokohama (JP)

(72) Inventors: Norihito Masuda, Yokohama (JP); Hiroaki Sato, Yokohama (JP)

(73) Assignee: INVENSAS CORPORATION, San Jose, CA (US)

(21) Appl. No.: 13/207,059

(22) Filed: Aug. 10, 2011

(51) Int. Cl. H05K 1/09; B32B 38/08; H05K 1/18; H05K 1/00; H05K 1/11; B05D 3/06; B32B 38/10

(52) U.S. Cl. 174/257; 427/555; 156/272.8; 174/250; 174/261; 174/260

(57) ABSTRACT

A method for making a microelectronic substrate includes forming a pattern of a selected metallic layer of an in-process unit using laser ablation such that the pattern corresponds to desired locations for conductive features. Conductive material is than added to the in-process unit by a process that uses the pattern to concentrate application of the conductive material to the in-process unit such that the conductive material forms conductive features of the substrate according to the pattern. The step forming a pattern of a selected metallic layer of an in-process unit using laser ablation can includes the use of a UV laser, a CO2 or an excimer laser.

### BACKGROUND OF THE INVENTION

Microelectronic structures include various forms of wiring or circuitry to conduct electrical currents between elements included therein. Such wiring is often formed on various substrates and can include traces interconnecting contact pads or the like. Ever smaller microelectronic structures are desired, and trace formation can be a factor that prohibits the formation of small structures. The width of traces can vary according to the material from which the traces are made and the conditions under which the trace will operate. Such conditions include the type of current the trace carries (such as a signal, a ground connection, etc.), the heat generated in the surrounding structure, and the amount of current that the trace will carry.

The distance between traces or other such features on a substrate, however, can be dictated by the process used to make the traces. The process used can influence the distance between the traces based on the resolution or accuracy of the process used and the uniformity of the application of conductive material thereby. Processes such as those using lithography or screen printing can be limiting because of the resolution they provide, which can require a greater distance between conductive features to account for tolerances within the procedures. Similarly, etching, which is often used to remove portions of a solid metal layer to form traces or other contacts, can be difficult to control or can otherwise result in larger tolerances, particularly with respect to chemical etching.

Cost is a further consideration in manufacturing microelectronic components, including those having traces. Accordingly, in reductive procedures, such as etching traces from a solid metal layer, the use of costly materials such as copper, gold, or the like, that are ultimately removed can lead to increased cost for the entire product. Accordingly, further methods for trace formation or the formation of other conductive features on a substrate are desired.

SUMMARY OF TEE INVENTION

An embodiment of the present disclosure relates method for making a microelectronic substrate. The method includes forming a pattern of a selected metallic layer of an in-process unit using laser ablation such that the pattern corresponds to desired locations for conductive features. Conductive material is than added to the in-process unit by a process that uses the pattern to concentrate application of the conductive material to the in-process unit such that the conductive material forms conductive features of the substrate according to the pattern. The step forming a pattern of a selected metallic layer of an in-process unit using laser ablation can includes the use of a UV laser, a CO2 or an excimer laser.

The selected metallic layer can be a catalyst layer formed extending along a first dielectric layer of the in-process unit. The pattern can be formed by removing selected portions of the catalyst layer, and the pattern can be defined by the portions of the catalyst layer remaining on the dielectric layer after laser ablation. The catalyst layer can include, for example, palladium. The conductive material can be added by an electroless plating process such that the conductive material forms on the catalyst layer defining the pattern.

The first dielectric layer can be a first layer of a multilayer substrate that includes conductive features underlying the first dielectric layer, and the first dielectric layer can include a plurality of vias formed therein to expose selected portions of the conductive features on an outside surface thereof. The pattern can include portions of the catalyst layer that extend along at least portions of the vias and contact the selected portions of the conductive features. The multilayer substrate can include a layer having conductive features formed over a patterned catalyst material.

The conductive features can include conductive pads and traces interconnecting at least some of the conductive pads. A method for making a microelectronic package can include bonding a microelectronic unit to a made according to the above method. The microelectronic element can have a front surface, a back surface and contacts exposed on the first surface. At least some of the contacts can be electrically connected to at least some of the pads of the substrate.

Another embodiment of the present disclosure relates to a method for making a microelectronic substrate. The method includes forming a pattern in a selected dielectric layer of an in-process unit using laser ablation, such that the pattern corresponds to desired locations for conductive features. Conductive material is then added to the in-process unit by a process that uses the pattern to concentrate application of the conductive material to the in-process unit such that the conductive material forms conductive features of the substrate according to the pattern. The catalyst seed layer can include palladium. The step of forming a pattern in a selected dielectric layer of an in-process unit using laser ablation can include the use of a UV laser, a CO2 or an excimer laser.

The selected dielectric layer can have a first surface and a second surface remote therefrom, and the pattern can be defined by trenches formed in the dielectric layer such that they are open to the first surface and define lower surfaces between the first and second surfaces and edge surfaces between the first surface and the lower surfaces. The method can then further include the steps of adding a catalyst seed layer to the dielectric layer along the first surface, the edge surfaces and the lower surfaces, and removing the portions of the seed layer on the first surface. The conductive material can be added by an electroless plating process that causes the conductive material to selectively collect on the seed layer on the edge and lower surfaces. The seed layer can be removed from the first surface of the dielectric layer by mechanical polishing.

The dielectric layer can be a first layer of a multilayer substrate having second conductive features underlying the second surface thereof, and the dielectric layer can include conductive vias within the trenches that expose selected portions of the conductive features at the first surface of the dielectric layer. Further, the step of adding the catalyst seed layer can include adding the seed layer along at least a portion of the vias such that the first conductive features are electrically connected to the second conductive features.

The conductive features can include conductive pads and traces interconnecting at least some of the conductive pads. A method for making a microelectronic package can include making a microelectronic substrate according to the above method and bonding a microelectronic unit to the substrate. The microelectronic element can have a front surface, a back surface and contacts exposed on the first surface. At least some of the contacts can then be electrically connected to at least some of the pads of the substrate.

Another embodiment of the present disclosure relates to a method for making a microelectronic substrate. The method includes forming an element having a dielectric layer with first and second opposed surfaces and having a first indented pattern of depressions extending from the first surface towards the second surface, and a conductive layer extending along the first surface and within the depressions. Portions of the conductive layer outside of the patterned portions are then removed. In the method, the patterned portions can further form pads and traces interconnecting at least some of the pads. The conductive material layer can be formed from copper, gold, aluminum or nickel, and the conductive material layer can be formed on the dielectric layer by plating.

The step of forming an element having a dielectric layer can further include forming a conductive material layer on a dielectric layer having a first surface and a second surface remote therefrom along the first surface of the dielectric layer. The method can then further include forcing predetermined areas of the conductive layer toward the second surface of the dielectric layer, thereby forming a first indented pattern in the dielectric layer and a substantially identical second indented pattern in the conductive layer such that patterned portions of the conductive layer are disposed between the first surface and the second surface of the dielectric layer. In the method, forcing predetermined areas of the conductive material layer toward the second surface of the dielectric layer can be carried out using a stamp having a negative image of the first predetermined pattern thereon.

Another embodiment of the present disclosure relates to microelectronic substrate having a plurality of electrically conductive elements of a first wiring layer overlying defining a wiring pattern. The substrate also includes a dielectric layer including a first major surface, a second major surface parallel to the first major surface and defining a thickness therebetween. A plurality of platform portions define platform surfaces spaced above the first major surface at a distance of at least 5 μm and underlie the plurality of electrically conductive elements such that the platform surfaces correspond to the wiring pattern.

The microelectronic substrate can further include a plurality of metallic layer elements between the conductive elements of the first wiring layer and the platform surfaces, and the metallic layer can correspond to the wiring pattern. The plurality of metallic layer elements can be in a catalyst layer between the wiring layer and the dielectric layer or the metallic layer elements can be of a catalyst material. The catalyst material can include palladium.

The electrically conductive elements can include contact pads and traces interconnecting at least some of the contact pads. A microelectronic package can include such a substrate and a microelectronic element including a front surface, a back surface, and contacts exposed on the first surface. The microelectronic element can be bonded to the substrate and at least some of the contacts thereof can be electrically connected to at least some of the pads of the substrate.

Another embodiment of the present disclosure relates to microelectronic substrate having a dielectric layer including a first major surface, a second major surface parallel to the first major surface and defining a thickness therebetween, and a plurality of indented portions open to the first major surface and defining a rounded indented surface extending away from the first surface and toward the second surface. The substrate also includes a plurality of electrically conductive elements at least partially within and filling the first indented portions of the dielectric layer, wherein the indented portions and the electrically conductive elements define a wiring pattern for the substrate. Portions of the conductive elements can extend above the first surface of the dielectric layer.

In the microelectronic substrate the conductive elements can define respective lengths and widths, and the conductive elements include multiple layers of conductive material defining grain structures thereof. In a cross-section along respective widths of the elements, the grain structures can define a concentric arcuate structure.

The electrically conductive elements can include contact pads and traces interconnecting at least some of the contact pads. A microelectronic package can include such a substrate and a microelectronic element including a front surface, a back surface, and contacts exposed on the first surface. The microelectronic element can be bonded to the substrate and at least some of the contacts thereof can be electrically connected to at least some of the pads of the substrate.

### BRIEF DESCRIPTION OF THE DRAWINGS

Various embodiments of the present invention will be now described with reference to the appended drawings. It is appreciated that these drawings depict only some embodiments of the invention and are therefore not to be considered limiting of its scope.

FIGS. 1-5 show a microelectronic substrate during successive steps in a fabrication method thereof;

FIG. 6 shows a schematic view of aspects of a microelectronic substrate that can be made according to the method steps shown in FIGS. 1-5;

FIG. 7 shows a microelectronic package including an embodiment of a substrate according to an embodiment of the present disclosure;

FIG. 8 shows a further microelectronic assembly including the substrate shown in FIG. 7;

FIG. 9-16 show a microelectronic substrate during successive steps in a fabrication method thereof;

FIG. 17 shows the microelectronic substrate of FIG. 16 assembled with a microelectronic element;

FIGS. 18-21 show a microelectronic substrate during successive steps in a fabrication method thereof;

FIGS. 22-26 show a microelectronic substrate during successive steps in a fabrication method thereof; and

FIGS. 27-30 show a microelectronic substrate during successive steps in a fabrication method thereof.

### DETAILED DESCRIPTION

Turning now to the figures, where similar numeric references are used to refer to similar features, a method according to an embodiment of the present disclosure for making a microelectronic substrate 10 is shown in FIGS. 1-3. An in-process unit 10′, as shown in FIG. 1 includes a dielectric layer 12 having a first surface 13 and a second surface 15. The first and second surfaces 13,15 can be parallel to each other and can extend in lateral directions defining respective planes spaced apart at a distance defining the thickness of the substrate therebetween. Dielectric layer can be made from, for example, a sheet of polyimide or another polymeric material or composite material, e.g. resin or glass-reinforced epoxy such at BT resin or FR-4. Additional materials for dielectric layer 12 can include ceramic and glass.

A seed layer 14 of a catalyst material is deposited over first surface 13 of dielectric layer 12. Seed layer 14 can include a material selected for having properties that promote the growth of subsequent layers or coatings of other metallic materials thereon by processes such as electroless plating and the like. Generally, such plated metallic coatings do not form directly on dielectric materials and the deposition of a seed layer or a catalyst layer is one way to allow for the indirect formation of such a layer on a dielectric layer. In an embodiment seed layer 14 is of a material that includes palladium. Seed layer can be deposited on dielectric layer 12 by, for example, a bath, including an electroless bath, or sputtering, including evaporation sputtering.

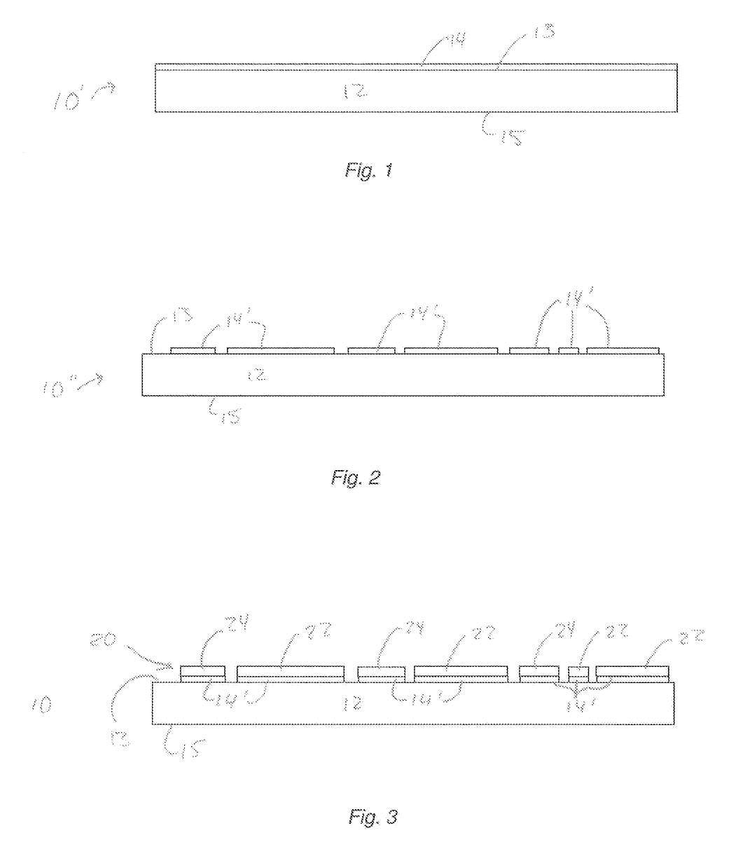

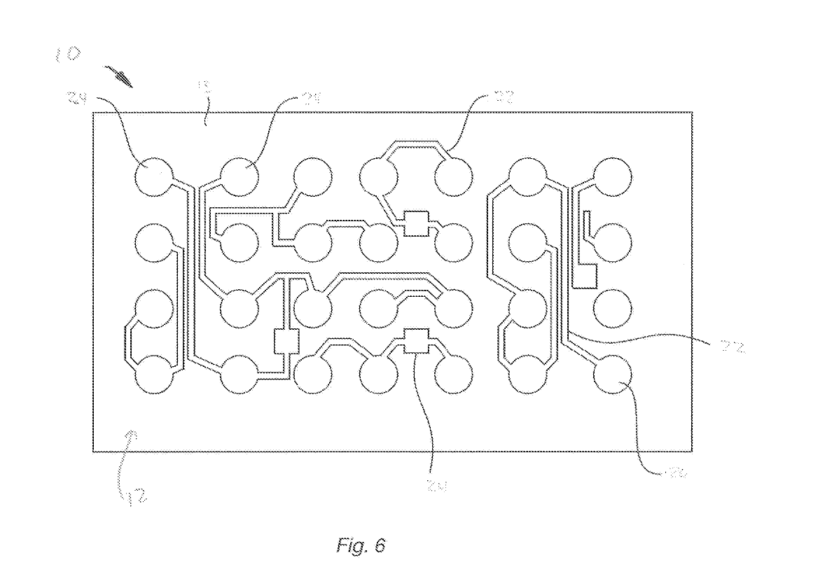

FIG. 2 shows in-process unit 10″ after removal of selected portions of seed layer 14. Portions of seed layer 14 are removed to form patterned elements 14′ that correspond to a desired wiring pattern for substrate 10. A plan-view of an example of a wiring pattern is shown in FIG. 6 in which the pattern can include, for example, portions thereof corresponding to desired locations contact pads and traces connected to the contact pads, both of which can be formed in a subsequent step. Such wiring patterns can be distributed over a predetermined area of surface 13, which can include the entire dielectric layer 12, or selected regions thereof. Accordingly, seed layer 14 can be deposited, as in FIG. 1, to cover all of first surface 13 or over selected portions thereof that are at least as large as the desired area of surface 13 in which patterned elements 14′ are to be formed.

Any one of various means for removing seed layer can be used. Such means include mechanical or chemical etching or the like. In an embodiment of the method described herein laser ablation can be used. Laser ablation uses a focused laser beam of a predetermined intensity to vaporize the portions of seed layer 14 outside the desired area for patterned portions 14′. Examples of types of lasers that can be used for ablation of portions of seed layer 14 include a CO2 laser, an ultraviolet light (“UV”) laser or an Excimer laser, among others. The intensity and exposure time that is used to remove portions of seed layer 14 can vary depending on the composition of seed layer 14, the thickness of seed layer 14, and the type of laser used, among other factors. In one example, a UV laser can be used having a fluence of between 10 and 500 mJ and can be applied to the seed layer over a predetermined number of pulses ranging from 1 to 30, depending on the thickness and composition of the seed layer and the actual fluence of the laser. The pulses for such a laser can be applied at a rate of between 5 and 70 kHz, and any feed rates or exposure durations can be of a rater or time determined to give the desired number of pulses given a predetermined pulse frequency. In another example an Excimer laser can be used having a fluence of between 10 and 2000 mJ and can be applied over between 1 and 30 pulses, as needed. In an embodiment of the method described herein, the use of laser ablation can give more control over the geometry of the patterned elements 14′ to be formed, which can allow for both the elements 14′ themselves, including those used to form traces, and the distance between them to be smaller. The formation of smaller and closer-together features can allow for more electrical interconnections in a smaller area, as well as more contacts at a finer pitch within a finished substrate. When using substrates formed by the methods described herein to package microelectronic elements and the like, it may be possible to prepare substrates that have a desirable pitch of conductors thereon and achieve desirable form factors in the assembled package.

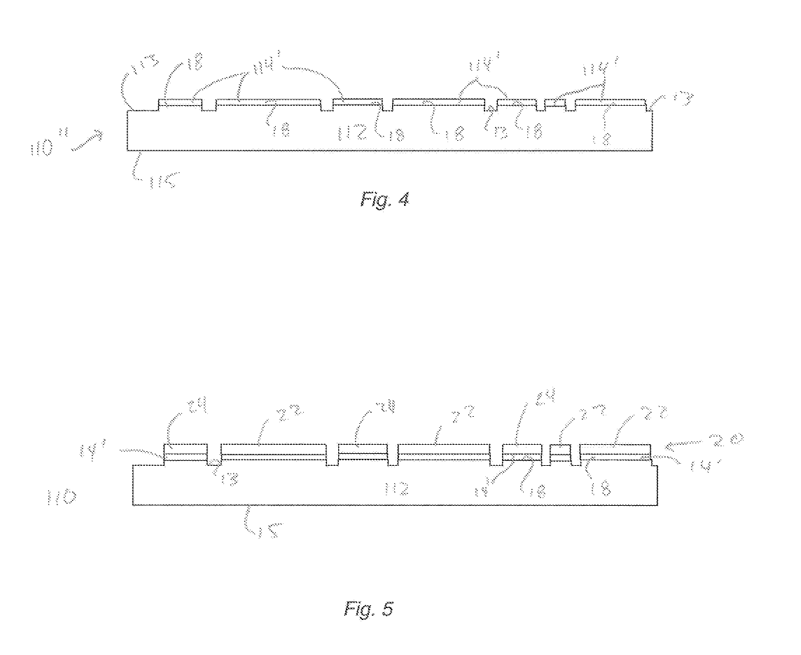

In another embodiment, shown in FIG. 4, the material removal process, such as that carried out by laser ablation or the like, can also remove a portion of the dielectric layer 112 in in-process unit 110″. This can be done, for example, by increasing either the power of the laser beam used for material removal or by increasing the exposure of the in-process unit 110″ to the laser beam in the selected areas thereof. This can result in removal of the seed layer 114 material and some of the dielectric layer 112. The resulting structure in such an embodiment can result in first major surface 113 being spaced below a plurality of platform surfaces 118 with portions of the dielectric layer 112 therebeneath. In an embodiment platform surfaces 18 can be spaced above first major surface by at least 1 μm. In another embodiment, platform surfaces 18 can be spaced above first major surface 113 by between 5 and 100 μm. In this embodiment the shape and configuration of platform surfaces 118 can correspond to the shape and configuration of patterned seed elements 14′. In other words, platform surfaces 18 can be positioned directly below and can be shaped to match the shape of patterned seed elements 14′.

As shown in FIG. 3, the embodiment of FIG. 2 is subjected to a plating process, which can be an electroless plating process, for example, to form substrate 10. Such a process can be carried out by electroless plating of a conductive metallic material that builds up on the patterned seed portions 14′, such that a wiring layer 30 is formed over the patterned seed portions 14′. The wiring layer 20 can include traces 22 and contact pads 24 interconnected by at least some of the traces. As described the configuration of the wiring layer 20 can be dictated by the configuration of the patterned seed portion 14′. As such, the wiring layer can be formed to the desired configuration by using the mechanical removal process shown in FIG. 3, such as by laser ablation, to form a corresponding pattern of patterned seed portions 14′ from seed layer 14.

As discussed above, the seed layer can be formed from a material including palladium. The seed layer can be further formed of a material that promotes and concentrates growth of the conductive material for wiring layer 20 thereon. Materials that can be used to form wiring layer 20 include copper, gold, nickel, aluminum, or combinations thereof. The material selected for wiring layer 20 is one that will not build up on dielectric layer 12 in areas that are not coated with seed layer 14 or patterned seed portions 14′. The plating process can be carried out using varying concentrations of the material to be deposited and over varying lengths of time to form the desired thickness of wiring layer 20, which can depend on the material deposited or the desired application for substrate 10. An exemplary pattern for wiring layer 20, including various traces 22 and contact pads 24, is shown in FIG. 6.

FIG. 5 shows a variation of a substrate 110 having a wiring layer 120 formed on patterned seed portions 114′ that are formed on the platform surfaces 118 described with respect to FIG. 4, above. The procedure for forming wiring layer 120 can be substantially identical to, and in any of the variations thereof, described above with respect to FIG. 3. The resulting substrate 110 includes wiring layer 20 which extends to a greater distance over first major surface 113, with substantially the same amount of material deposited, than would be possible with the embodiment of substrate 12 of FIG. 3.

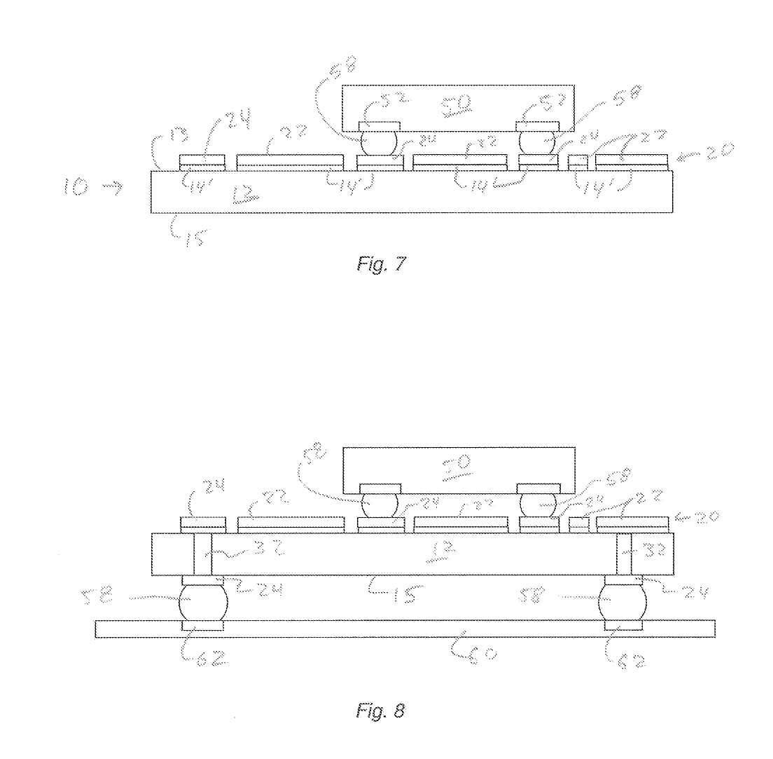

As shown in FIG. 7, substrate 10 can be assembled with a microelectronic element 50. In the embodiment shown microelectronic element is assembled with substrate 10 in a flip-chip configuration with front surface 54 thereof facing first major surface 13 of substrate 10. In this embodiment, the contacts 52 of microelectronic element 10 are mechanically and electrically connected to some of the contact pads 24 of substrate 10 using solder balls 58 or the like. Other ways of mounting microelectronic element 50 on substrate 10 are possible, including face-up mounting or the like. The resulting microelectronic package 70 can then be mounted on a circuit panel 60 or the like as shown in FIG. 8. As shown, terminals of the package 70 at surface 15 can be bonded to contact pads 62 of circuit panel 60, such as through solder balls 58. In other embodiments, substrate 10 can include contacts pads (not shown) at a surface 13 form bonding to corresponding contacts of a circuit panel. A circuit panel, such as the one shown in FIG. 8, can be made by any of the methods described herein, including those shown in FIGS. 1-9. Additionally, a microelectronic element, such as microelectronic element 50, or other microelectronic component can be mounted directly to a circuit panel, such as a circuit panel made by the methods described herein.

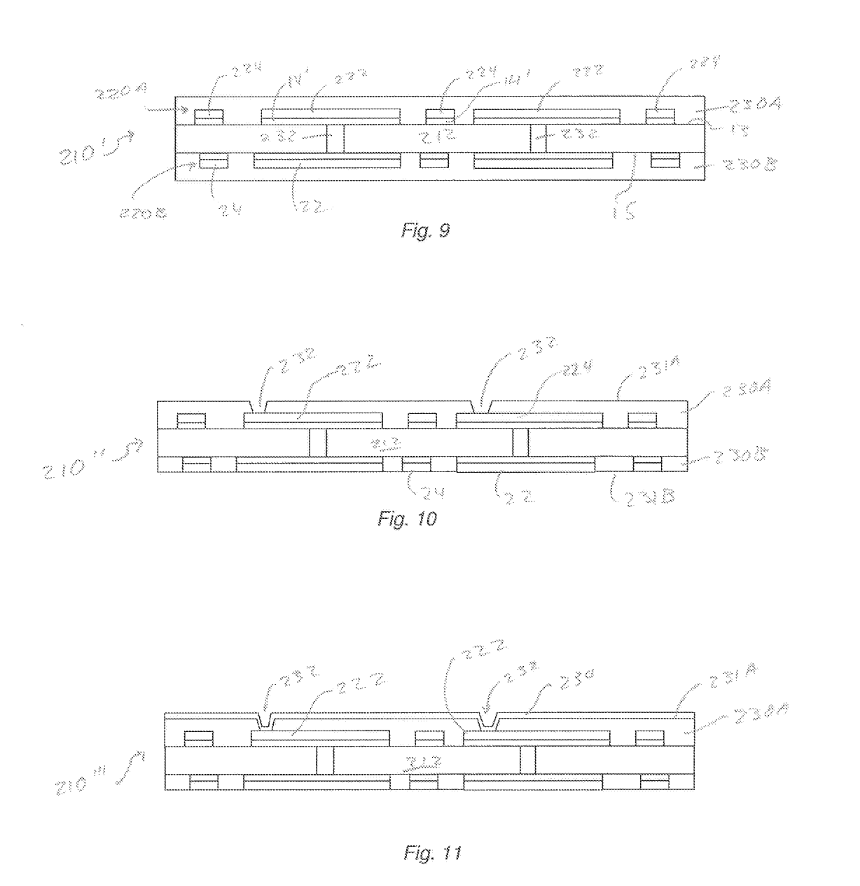

FIGS. 9-16 show stages in a method that can be used to form a multilayer substrate 210 using repetition of the steps discussed in FIGS. 1-5. As shown in FIG. 9, an in-process unit 210′ is shown having a wiring layer 220A formed over the first major surface 213 of dielectric layer 212. Another wiring layer 220B is formed over second major surface 215. Wiring layers 220A and 220B can be made according to the methods described in 1-3, which can further include the variations of FIGS. 4 and 5, or they can be formed using other methods for forming wiring layers. Second dielectric layers 230A and 230B are formed covering wiring layers 220A and 220B, as shown in FIG. 9. In FIG. 10, dielectric layer 230B has a portion thereof mechanically removed to expose at least portions of wiring layer 220B thereat for connection to external structures or devices. Alternatively, contact pads can be formed on dielectric layer 230B, which can be done in steps described below or using other methods.

Additionally, FIG. 10 shows a plurality of vias 232 formed in dielectric layer 230A such that portions of wiring layer 220 are exposed at major surface 231 of dielectric layer 230A. In FIG. 11 a second seed layer 234 is formed over major surface 231 and at least coating vias 232 of dielectric layer 230A. Second seed layer 234 can be formed by the method described above in FIG. 1 and can be formed by similar materials with similar considerations as to the size and position of the area that it covers, which can include the entire area of surface 231 and any vias 232 formed therein.

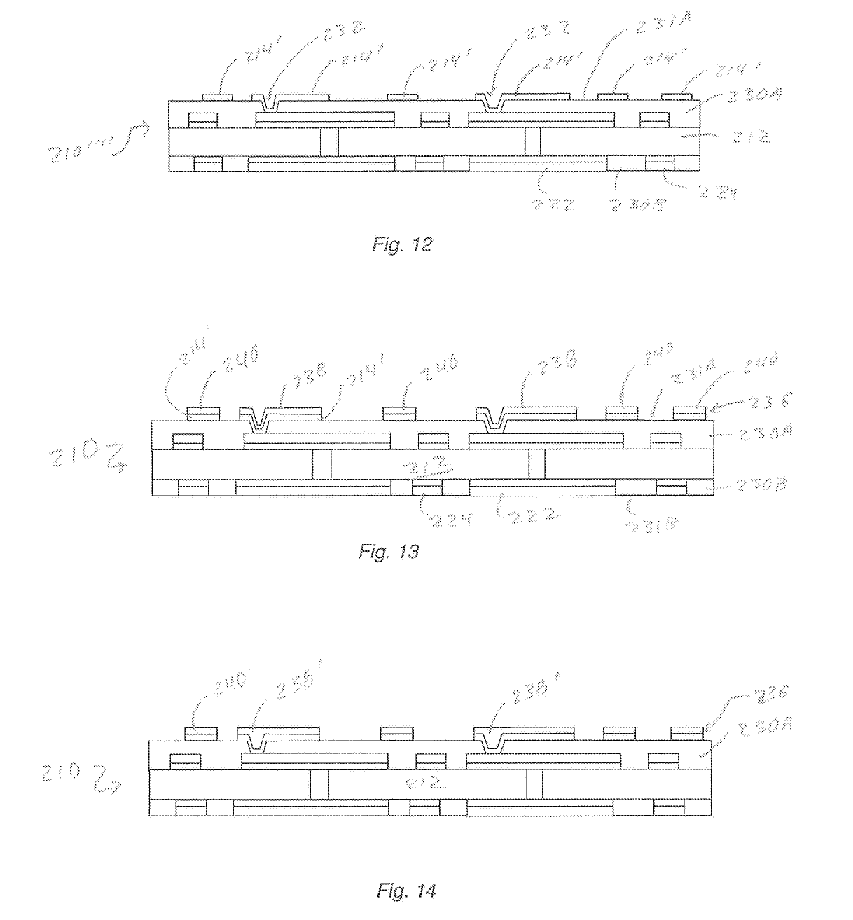

As shown in FIG. 12, seed layer 234 is then subjected to a removal process to form a plurality of patterned seed portions 234′ on surface 231. The removal process can be any of those described above with respect to FIG. 2, including laser ablation. Further the removal process preferably results in the patterned seed portions 234′ corresponding to a desired pattern for a second wiring layer 236 that can be formed using the patterned seed portions 234′, as shown in FIG. 13. In the multilayer process described herein, the portions of seed layer 234 that coat vias 232 can be left in place as parts of at least some of the patterned seed portions 234′.

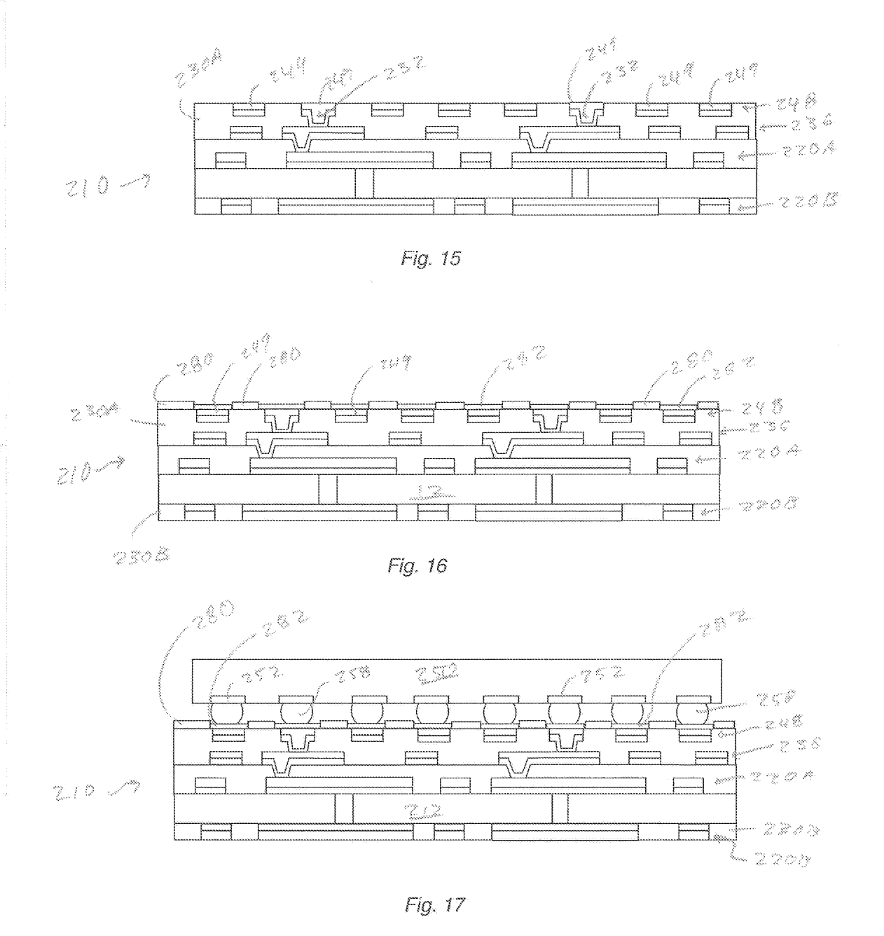

Second wiring layer 236 can be formed using an additive process, such as electroless plating, as described above with respect to FIG. 3, which can include similar materials and process considerations. Second wiring layer 236 can have similar characteristics to the wiring layer shown in plan view in FIG. 6, and can include traces 238 and contact pads 240 interconnected by some of the traces 238. Additionally, vias 232 coated by any of the patterned seed portions 234′ can have a part of the wiring layer 236 form therealong such that wiring layer 236 is electrically connected with wiring layer 220. If needed, any portions remaining open after the additive process within vias 232 can be filled by depositing conductive metal therein, as shown in FIG. 14. Subsequent additional wiring layers can be formed over and interconnected with wiring layer 236 by repeating this procedure as desired. An example of a further additional wiring layer is shown in FIG. 15, wherein wiring layer 248 includes a plurality of contact pads 249. If desired, a solder mask layer 280 can be formed over the uppermost dielectric layer and additional contact pads 282 can be formed in holes formed therein and can be electrically connected with the contact pads 249 of wiring layer 248. These contacts can be used for mounting a microelectronic element 250 that can be mounted to substrate 210 using flip-chip bonding, as shown in FIG. 17, or using other mounting methods. The above process can be used to form additional wiring layers over wiring layer 220B.

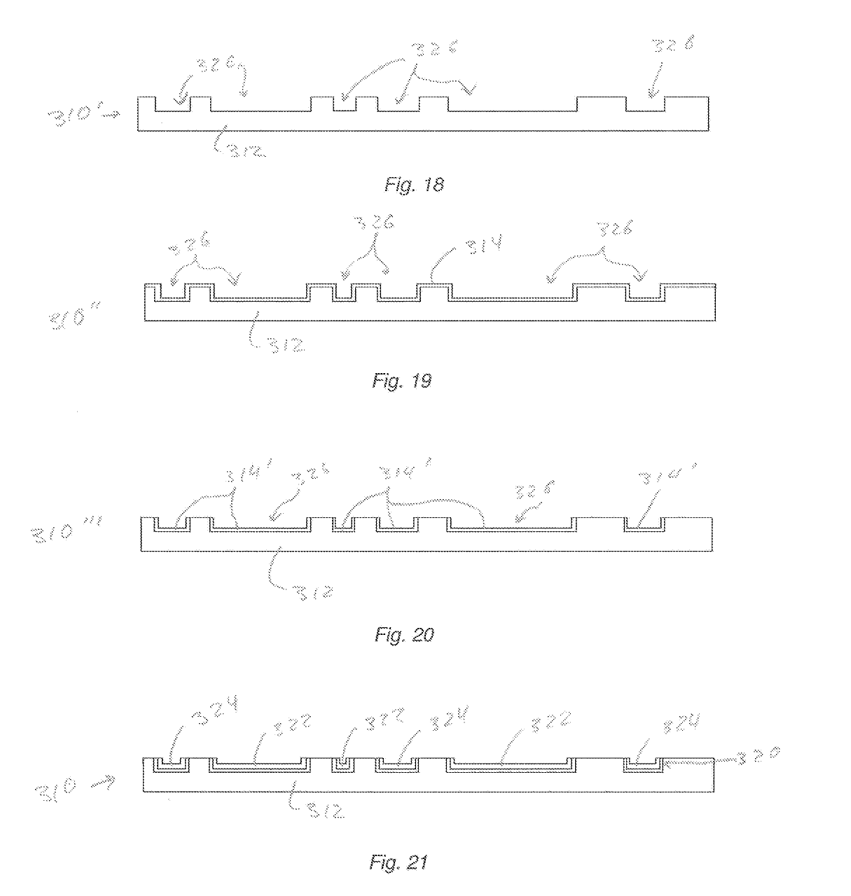

FIGS. 18-21 show stages in a method for making a microelectronic substrate 310 according to another embodiment. As shown in FIG. 18, a dielectric layer 312 has a plurality of trenches 326, e.g. blind openings, formed therein that are open to and extend below first major surface 313. Trenches 326 can be formed by a removal process similar to those used to remove portions of seed layer 14 in the method discussed above with respect to FIG. 1. As previously discussed, one method that can be used to form trenches 326 is laser ablation, wherein a focused laser beam is used to remove material in a desired area. The use of laser ablation to remove portions of dielectric layer 312 to form trenches 326 can be similar to the use thereof to remove portions of seed layer 14, as discussed above, with adjustments to, for example, the intensity of the laser beam, and the duration of exposure to compensate for differences in geometry and the difference in material to be removed. For example, the trenches 326 can have a depth that is greater than a thickness of the seed layer 14 discussed above, thus requiring more material removal in a given area.

While the seed layer 14 of FIG. 1 is removed in areas outside the desired pattern for the wiring layer 20 to be formed in FIG. 3, the material removed from dielectric layer will correspond to the areas that are to include portions of the wiring layer 320, as discussed below and shown in FIG. 121. Therefore, the material that is removed by laser ablation will form trenches 326 that correspond to a predetermined configuration for traces and contact pads that will be formed in a wiring layer, an example of which is shown in FIG. 6. The depth of the trenches can vary depending on the amount of material to be deposited in a wiring layer (i.e. the thickness of the features in the wiring layer) or to give the elements in the wiring layer certain geometric characteristics. In one example, as will be seen below, the wiring layer features can be given a U-shaped configuration by making the width and depth of the trenches greater than the desired thickness of material to be deposited for the wiring layer. In another example, the wiring layer features can be rounded along the bottom surface or at least the bottom corners thereof, by forming the trenches 326 with a corresponding geometry. Further configurations are possible and can be imparted on trenches 326 through control of a laser beam, or other process, used to form them.

As shown in FIG. 19, a seed layer 314 is then deposited on dielectric layer 312 including over first major surface 313 and within trenches 326. The seed layer can be deposited using the procedures discussed above with respect to FIG. 1, including the material and geometric considerations discussed in connection therewith. The portions of the seed layer 314 that are formed on the first major surface 313 are then removed as shown in FIG. 20. Because the trenches, and the portions of seed layer 314 formed therein, are set beneath first major surface 313, mechanical removal processes that act on a plane, can be used for such removal. For example, a polishing process using a disk or other substantially planar support can be used by positioning the disk against over first major surface 313 and by polishing down the seed layer 314 until the portions in contact with the disk (i.e. the portions over first major surface 313) have been removed. This leaves the portions of the seed layer 314 within the trenches 326 within the in-process unit 310″ as patterned seed portions 314′, as they are spaced apart and protected from the planar removal apparatus. A grinding process similar to the polishing process discussed above can also be used, as can other processes. A subsequent cleaning process may be used to remove any debris within trenches 326 that is left by the removal process. Washing with various solutions can be used, as can blowing with, for example, compressed air, or brushing.

The resulting patterned seed portions 314′ correspond to the location and configuration of trenches 326 once the removal process has been completed. As such, a wiring layer 320 can be made on substrate 310 by depositing a conductive metal onto patterned seed portions 314′ using an additive process, such as electroless plating, similar to the processes discussed above with respect to FIG. 3. The amount of conductive metal material deposited over patterned seed portions 314′ can depend on the desired thickness for the wiring layer 320, including the traces 322 and contact pads 324 formed therein. Additionally, the amount of material deposited can depend on the geometry of trenches 326 and the desired shape of the wiring layer elements, including how they can correspond to the shape of the trenches 326. For example, the U-shaped features of FIG. 21 can be achieved by adding enough material to wiring layer 320 to cover patterned seed portions 314′ at a thickness sufficient for the desired conductivity, but not so thick as to completely fill the trenches 326. Additional material could be added to the substrate 310 shown in FIG. 21 to completely fill trenches 326, if desired. Similar considerations can be taken into account given different geometry for trenches 326.

The substrate 310 of FIG. 21 can be used for packaging of a microelectronic element, as shown with substrate 10 in FIG. 7. The resulting package can then also be assembled with a circuit panel or the like in a similar manner as is shown with package 70 in FIG. 8 or in the additional manners described in connection therewith.

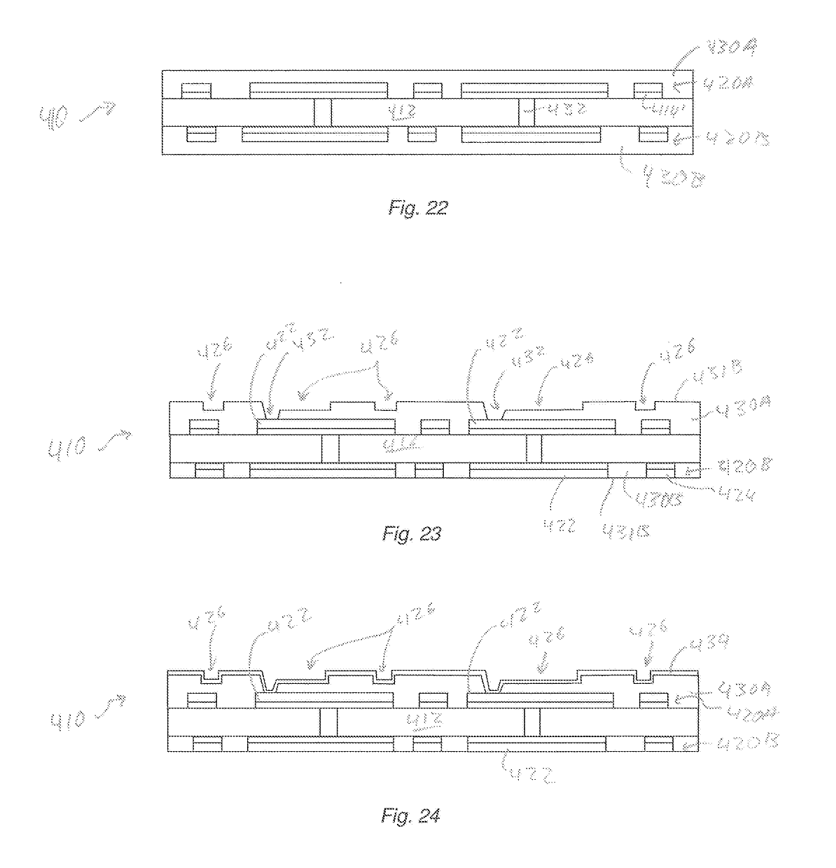

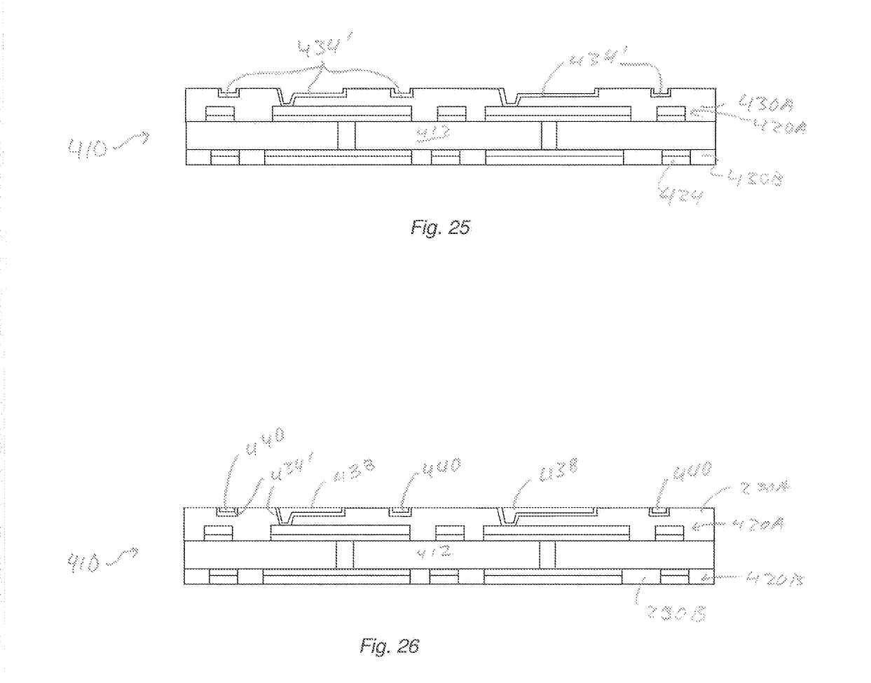

FIGS. 22-26 show stages in a fabrication method that can be used to form a multilayer substrate 410, as shown in FIG. 26. An in-process unit 410′ is shown in FIG. 22 that includes two wiring layers 420A and 420B formed on opposing sides 413 and 415 of a dielectric layer 412. Second dielectric layers 431A and 431B are formed over respective wiring layers on opposing sides of the dielectric layer 412. As shown in FIG. 23, a portion of dielectric layer 431B is removed to expose wiring layer 420B, including contact pads 424 for connection with an external structure. Alternatively, the procedure that will be discussed with respect to dielectric layer 431A can be carried out on wiring layer 431B. The wiring layer can be similar to that which is shown in FIGS. 18-21, in other embodiments discussed herein, or in accordance with any other method or structure.

Layer 431A is shown in FIG. 23 with trenches 426 corresponding to the desired location and configuration for an additional wiring layer (shown below) to be formed over wiring layer 420A. The formation of this wiring layer can be similar to that which is discussed above with respect to FIGS. 9-14. Additionally, trenches 426 can be formed to include vias 432 that expose portions of wiring layer 420A for electrical connection through dielectric layer 430A. Vias 432 can be formed by the removal process that is used to form trenches 426, such as by laser ablation. Alternatively vias 432 can be formed by a different process after formation of trenches 426.

As shown in FIG. 24, seed layer 414 is then formed over surface 431 and coating trenches 426 and vias 434. Vias 434 are coated such that the seed layer 414 at least extends to contact a portion of wiring layer 420. Seed layer 414 can cover exposed portions of wiring layer 420 within vias 434. Seed layer 414 is applied on in-process unit 410′″ in a manner similar to other seed layers discussed herein. Portions of seed layer 414 that overly major surface 431 are then removed in a similar manner to the removal of portions of seed layer 314, described above. This process leaves patterned seed portions 414′ within trenches 426 and within vias 432. Wiring layer 436 is then added, through one of the processes discussed previously, including electroless plating, and of similar materials discussed elsewhere. Wiring layer 436 can form a predetermined wiring pattern including traces 438 and contact pads 440, as discussed above. Further, wiring layer 436 can connect to wiring layer 420 by the formation of portions of wiring layer 436 within vias 436. If desired, open portions of the wiring layer features can be filled with additional conductive metal, as shown in FIG. 26. Additional wiring layers or solder mask layers can be added, as discussed above with respect to FIGS. 15 and 16. Further, the resulting substrate 410 can be assembled with a microelectronic unit in a similar manner to that shown in FIG. 17.

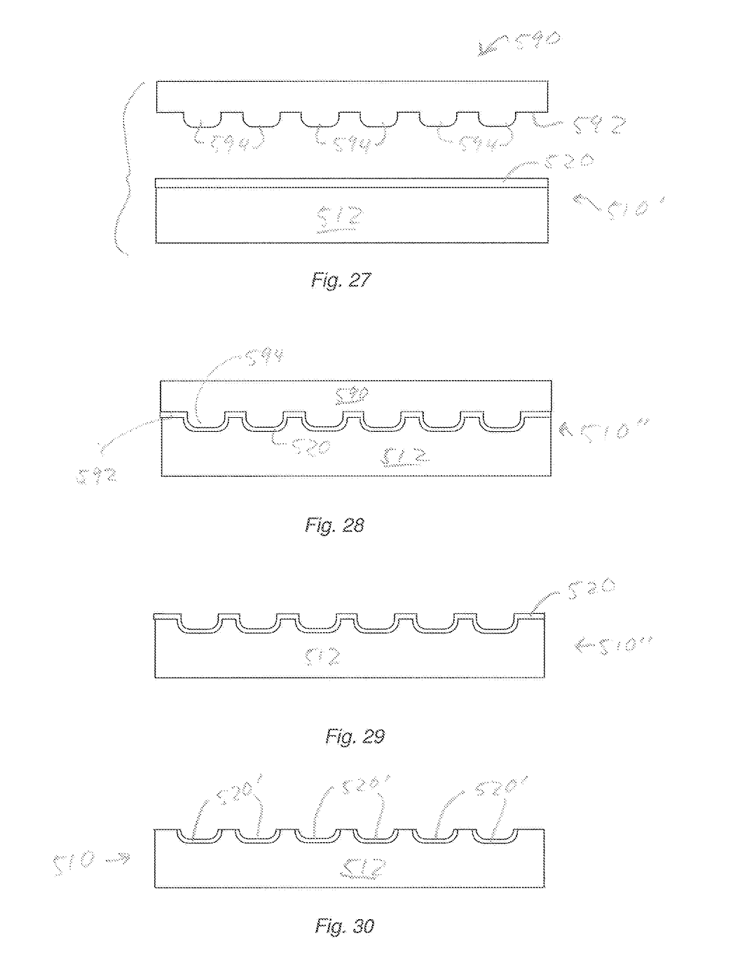

Stages in a further method for making a microelectronic substrate 510 are shown in FIGS. 27-30. In this method an in-process unit 510′ includes a dielectric layer 512 with a conductive metal layer 520 formed thereon. Conductive metal layer 520 can be formed using methods discussed herein for forming wiring layer 20, such as by electroless plating on a seed layer (not shown in FIG. 27) that can contain, for example, Palladium. Other methods for making in process-unit 510′ can be used.

A press unit 90 is also shown in FIG. 27. Press unit 590 can be used in a step of forming wiring layer 520′ in the substrate that can result from this method. Accordingly, press unit 590 includes a major surface 592 and a plurality of press elements 594 formed extending away from major surface 592. Press elements can be used to force areas of layer 520 into dielectric layer 512 in a step of making those areas into wiring elements 520′. Accordingly, press elements 594 can be formed to correspond to a pattern for wiring, including having shapes and locations corresponding to traces and contact pads interconnected by traces. This can be similar to the example shown in FIG. 6. Press elements 594 can extend above major surface 592 at a distance that is about equal to a desired depth at which layer 520 is to be pressed into dielectric layer 512. A number of cross-sectional profiles are possible for press elements 594. Examples of shapes include the rounded rectangular forms shown in FIG. 27, semicircular forms, and the like. In an embodiment, press unit 590 can be formed from metal, including aluminum, steel or other materials. A metal press unit 590 can be formed by first making a metal slab defining major surface 590 and then by depositing additional metal in the areas for press portions 594 such as by plating, stenciling or the like. Alternatively, a metal slab can be subjected to a removal process, such as by use of a milling process, etching, or using laser ablation. The removal process can remove material outside of the desired locations for press portions 594, forming major surface 492 therebetween. Press unit 590 can also be made from glass, ceramic or other materials.

As shown in FIG. 28, press unit 590 is forced into in-process unit 510″ such that major surface 592 and press portions both contact metal layer 520. In this step, portions of metal layer 520 are forced into dielectric layer 512 by press portions 594. As shown, the geometry of press portions, including both the cross-sectional shape and the overall pattern of press portions 594, is imparted in the portions of wiring layer 520 contacted by the press portions 594. Additionally, the wiring layer will deform such that any grain structure present in the wiring layer 520′ will deform in a corresponding manner. For example, if metal layer 520 is formed using a plating process, it will initially have a grain structure that shows the boundaries between the individual plating layers. These boundaries can be substantially parallel and planar to each other. In this example, after being pressed into dielectric layer 512, the grain structure will deform such that the boundaries follow the deformation of the outside surfaces of the wiring layer 520′, resulting in a cross-sectional structure in which the grain forms substantially concentric arcs through the thickness of the wiring layer in an area thereof. In the embodiment shown, these arcs may be located in the rounded corner sections of the wiring layer 520′. Other correspondingly similar grain structures can result from other cross-sectional shapes imparted on wiring layer 520′. Some additional deformation in the grain structure or in the overall form of wiring layer 520′ can occur due to, for example, the stress applied to wiring layer 520′ to achieve the desired shape thereof. Allowances in the geometry of press portions 594 to compensate for such deformation are contemplated, as would be dictated by material thickness and the characteristics of the dielectric layer material and the metal that comprises metal layer 520. The press unit 590 is removed, as shown in FIG. 29, leaving in-process unit 510′″, having portions of wiring layer displaced into dielectric layer 512, as shown.

After removal of press unit 590, wiring layer 520 is subjected to a process to remove portions thereof that were not pressed into dielectric layer 512 by press portions 594. This process is similar, in concept, to the removal process for seed layer 314 discussed with respect to FIG. 20 and can be done using similar methods, such as grinding or polishing. After the removal step patterned wire portions 520′ remain embedded in dielectric layer 512. These patterned wire portions 520′ can include both traces and contact pads interconnected by at least some of the traces, as discussed elsewhere herein. Further, substrate 510 can be used to package microelectronic elements and to assembly the resulting package with circuit panels or the like as also discussed elsewhere herein.

In a variation of the above method, press portions 594 can be formed having sharp corners along a cross-sectional profile thereof such that, when pressed into an in-process unit, such as that shown in FIG. 27, the metal layer 520 is pressed into dielectric layer 512 and is cut along the sharp corner. The sharp corner can substantially outline the portions of the wiring layer to be left embedded in dielectric layer 512 after the removal process. The cut made thereby can aid in the removal step by separating the portion of the metal layer to be left in the in-process unit and that which is to be removed. In such an embodiment a removal process such as peeling can be used to remove the un-needed portion of the metal layer.

Although the invention herein has been described with reference to particular embodiments, it is to be understood that these embodiments are merely illustrative of the principles and applications of the present invention. It is therefore to be understood that numerous modifications may be made to the illustrative embodiments and that other arrangements may be devised without departing from the spirit and scope of the present invention as defined by the appended claims.

1. A method for making a microelectronic substrate, comprising:
forming a pattern of a selected metallic layer of an in-process unit using laser ablation, wherein the pattern corresponds to desired locations for conductive features; and
adding conductive material to the in-process unit by a process that uses the pattern to concentrate application of the conductive material to the in-process unit;
wherein the conductive material forms conductive features of the substrate according to the pattern.

2. The method of claim 1, wherein the selected metallic layer is a catalyst layer formed extending along a first dielectric layer of the in-process unit, wherein the pattern is formed by removing selected portions of the catalyst layer, and wherein the pattern is defined by the portions of the catalyst layer remaining on the dielectric layer after laser ablation.

3. The method of claim 2, wherein the catalyst layer includes palladium.

4. The method of claim 3, wherein the conductive material is added by an electroless plating process such that the conductive material forms on the catalyst layer defining the pattern.

5. The method of claim 2, wherein the first dielectric layer is a first layer of a multilayer substrate that includes conductive features underlying the first dielectric layer, wherein the first dielectric layer includes a plurality of vias formed therein to expose selected portions of the conducive features on an outside surface thereof, and wherein the pattern includes portions of the catalyst layer that extend along at least portions of the vias and contact the selected portions of the conductive features.

6. The method of claim 4, wherein the multilayer substrate includes a layer having conductive features formed over a patterned catalyst material.

7. The method of claim 1, wherein the laser ablation includes the use of a UV laser, a CO₂ or an excimer laser.

8. The method of claim 1, wherein the conductive features include conductive pads and traces interconnecting at least some of the conductive pads.

9. A method for making a microelectronic package including:
making a microelectronic substrate according to claim 8;
bonding a microelectronic unit to the substrate, the microelectronic element having a front surface, a back surface and contacts exposed on the first surface; and
electrically connecting at least some of the contacts to at least some of the pads of the substrate.

10. A method for making a microelectronic substrate, comprising:
forming a pattern of a selected dielectric layer of an in-process unit using laser ablation, wherein the pattern corresponds to desired locations for conductive features; and
adding conductive material to the in-process unit by a process that uses the pattern to concentrate application of the conductive material to the in-process unit;
wherein the conductive material forms conductive features of the substrate according to the pattern.

11. The method of claim 10, wherein:
the selected dielectric layer has a first surface and a second surface remote therefrom, and
the pattern is defined by trenches formed in the dielectric layer such that they are open to the first surface and define lower surfaces between the first and second surfaces and edge surfaces between the first surface and the lower surfaces;
the method further including the steps of adding a catalyst seed layer to the dielectric layer along the first surface, the edge surfaces and the lower surfaces, and removing the portions of the seed layer on the first surface.

12. The method of claim 11, wherein the conductive material is added by an electroless plating process that causes the conductive material to selectively collect on the seed layer on the edge and lower surfaces.

13. The method of claim 11, wherein the seed layer is removed from the first surface of the dielectric layer by mechanical polishing.

14. The method of claim 11, wherein the dielectric layer is a first layer of a multilayer substrate having second conductive features underlying the second surface thereof, wherein the dielectric layer includes conductive vias within the trenches that expose selected portions of the conductive features at the first surface of the dielectric layer, and wherein the step of adding the catalyst seed layer includes adding the seed layer along at least a portion of the vias such that the first conductive features are electrically connected to the second conductive features.

15. The method of claim 11, wherein the catalyst seed layer includes palladium.

16. The method of claim 10, wherein the laser ablation includes the use of a UV laser, a CO₂ or an excimer laser.

17. The method of claim 10, wherein the conductive features include conductive pads and traces interconnecting at least some of the conductive pads.

18. A method for making a microelectronic package including:
making a microelectronic substrate according to claim 17;
bonding a microelectronic unit to the substrate, the microelectronic element having a front surface, a back surface and contacts exposed on the first surface; and
electrically connecting at least some of the contacts to at least some of the pads of the substrate.

19. A method for making a microelectronic substrate, comprising:
(a) forming an element including: a dielectric layer having first and second opposed surfaces and having a first indented pattern of depressions extending from the first surface towards the second surface, and a conductive layer extending along the first surface and within the depressions; and then
(b) removing portions of the conductive layer outside of the patterned portions.

20. The method as claimed in claim 19, wherein step (a) includes: forming a conductive material layer on a dielectric layer having a first surface and a second surface remote therefrom, the conductive material layer being formed along the first surface; and
forcing predetermined areas of the conductive layer toward the second surface of the dielectric layer thereby forming a first indented pattern in the dielectric layer and a substantially identical second indented pattern in the conductive layer such that patterned portions of the conductive layer are disposed between the first surface and the second surface of the dielectric layer.

21. The method of claim 19, wherein the patterned portions form pads and traces interconnecting at least some of the pads.

22. The method of claim 19, wherein the conductive material layer is formed from copper, gold, aluminum or nickel.

23. The method of claim 19, wherein the conductive material layer is formed on the dielectric layer by plating.

24. The method of claim 20, wherein the forcing predetermined areas of the conductive material layer toward the second surface of the dielectric layer is carried out using a stamp having a negative image of the first predetermined pattern thereon.

25. A microelectronic substrate comprising:
a plurality of electrically conductive elements of a first wiring layer overlying defining a wiring pattern;
a dielectric layer including a first major surface, a second major surface parallel to the first major surface and defining a thickness therebetween, and a plurality of platform portions defining platform surfaces spaced above the first major surface at a distance of at least 1 μm and underlying the plurality of electrically conductive elements such that the platform surfaces correspond to the wiring pattern.

26. The microelectronic substrate of claim 25, further including a plurality of metallic layer elements between the conductive elements of the first wiring layer and the platform surfaces, wherein the metallic layer corresponds to the wiring pattern.

27. The microelectronic substrate of claim 26, wherein the plurality of metallic layer elements are in a catalyst layer between the wiring layer and the dielectric layer.

28. The microelectronic substrate of claim 26, wherein the metallic layer elements are of a catalyst material.

29. The microelectronic substrate of claim 28, wherein the catalyst material includes palladium.

30. The microelectronic substrate of claim 25, wherein the electrically conductive elements include contact pads and traces interconnecting at least some of the contact pads.

31. A microelectronic package, including:
the substrate of claim 30; and
a microelectronic element including a front surface, a back surface, and contacts exposed on the first surface, the microelectronic element being bonded to the substrate and at least some of the contacts thereof being electrically connected to at least some of the pads of the substrate.

32. A microelectronic substrate, comprising:
a dielectric layer including a first major surface, a second major surface parallel to the first major surface and defining a thickness therebetween, and a plurality of indented portions open to the first major surface and defining a rounded indented surface extending away from the first surface and toward the second surface; and
a plurality of electrically conductive elements at least partially within and filling the first indented portions of the dielectric layer, wherein the indented portions and the electrically conductive elements define a wiring pattern for the substrate.

33. The microelectronic substrate of claim 32, wherein the conductive elements define respective lengths and widths, wherein the conductive elements include multiple layers of conductive material defining grain structures thereof, and wherein in a cross-section along respective widths thereof, the grain structures that defines a concentric arcuate structure along at least a portion thereof.

34. The microelectronic substrate of claim 32, wherein portions of the conductive elements extend above the first surface of the dielectric layer.

35. The microelectronic substrate of claim 32, wherein the electrically conductive elements include contact pads and traces interconnecting at least some of the contact pads.

31. A microelectronic package, including:
the substrate of claim 35; and
a microelectronic element including a front surface, a back surface, and contacts exposed on the first surface, the microelectronic element being bonded to the substrate and at least some of the contacts thereof being electrically connected to at least some of the pads of the substrate.
